(19) United States
(12) Patent Application Publication
(10) Pub. No.: US 2006/0134813 A1
(43) Pub. Date: Jun. 22, 2006

(54) Organic light-emitting panel, package process for organic light-emitting panel and coating apparatus thereof

(76) Inventors: Mao-Kuo Wei, Banciao City (TW); Yuang-Wei Lai, Hsinchu (TW)

Correspondence Address: J.C. Patents, Suite 250, 4 Venture, Irvine, CA, 92618, US

(21) Appl. No.: 11/340,020

(22) Filed: Jan. 25, 2006

Related U.S. Application Data
(62) Division of application No. 10/692,642, filed on Oct. 24, 2003.

(30) Foreign Application Priority Data
Oct. 25, 2002 (TW) 91125118

(51) Int. Cl. H01L 21/56

(52) U.S. Cl. 438/26; 438/795

(57) ABSTRACT

An organic light-emitting panel, a process for packaging an organic light-emitting panel and a coating apparatus applied thereto are described. A patterned desiccant with large surface area is formed on a cover plate by an ink-jet printing process. The process for packaging an organic light-emitting panel and the coating process are applied for reducing crosslinking time of the desiccant, increasing the surface area of the desiccant and enhancing the moisture absorption ability of the desiccant.

### CROSS-REFERENCE TO RELATED APPLICATION

This application claims the priority benefit of Taiwan application serial no. 91125118, filed Oct. 25, 2002.

### BACKGROUND OF THE INVENTION

1. Field of the Invention

The present invention relates to a panel, a package process and a coating apparatus, and more particularly to an organic light-emitting panel, a package process for organic light-emitting panel and coating apparatus thereof.

2. Description of the Related Art

Organic light-emitting devices (OLEDs) use illumination of organic functional material property for displaying. The device is formed by a pair of electrodes and an organic functional layer disposed between the electrodes and could be divided into small molecule OLED (SM-OLED) or polymer light-emitting device (PLED) depending on the organic functional material applied thereto.

When current flows through the transparent anode and the metal cathode, holes and electrons will recombine within the organic functional layer and generate photons. The different colored lights are determined by the material property of the organic functional layer.

OLED is widely used in cellular phones, PDA and various displays. Because of the advantages of OLED, such as self-luminescence, wide viewing angle, simple process, low cost, fast response speed, low driving voltage, wide temperature application and full color, it has become the mainstream of development.

The package process of OLED is also an important development subject. The process is performed in inert gas environment and an ultraviolet-solidified adhesive frame is formed on the glass substrate around the OLED. The organic functional material and the cathode in OLED easily interact with moisture and oxygen and leading to the formation of dark spots and degradation of devices. Therefore the OLED is protected from erosion due to moisture and oxygen by attaching a glass cover to the substrate glass.

However, because the adhesive frame is polymer and has a width about 1 mm, moisture easily penetrates through the adhesive frame. Therefore, it cannot completely protect OLED from moisture and oxygen and the life time of OLED is shortened. Therefore, non-illumination area or dark spots are generated and the device becomes degraded. Accordingly, it is important to remove moisture and oxygen from OLED.

Therefore, the traditional method to resolve the issue uses desiccant in the process for absorbing the moisture in the space between the cover glass and the glass substrate. The process of forming the desiccant therein is performed by a spin-coating process. Although the coating process is a short time process, more than 90% desiccant is wasted and thereby increases the manufacturing costs. In addition, the traditional process needs longer solidification time because the solvent of the desiccant is hard to evaporate. It also has disadvantages of small moisture absorption area and poor moisture absorption ability. Although a dispensing process can be alternatively used to form the desiccant on the cover glass, however the dispensing process is a long time process, and besides a thickness of the desiccant is about hundreds μm and a cover glass having a deep trench should be used. Therefore, the cover glass is easy to crack. Moreover, the process also needs longer solidification time because the solvent of the desiccant is hard to evaporate.

### SUMMARY OF THE INVENTION

Therefore, an object of the present invention is to provide an organic light-emitting panel, a package process for organic light-emitting panel and a coating apparatus for resolving the issues of desiccant, reducing process time and manufacturing costs and protecting the panel.

Another object of the present invention is to provide a package process for organic light-emitting panel for reducing the crosslinking time of desiccant, increasing surface area of the desiccant and improving moisture-absorption ability thereof.

The other object of the present invention is to provide a package process for organic light-emitting panel for efficiently protecting the organic light-emitting panel from erosion due to moisture and oxygen.

According to the objects described above, the present invention discloses a method for forming desiccant. The method comprises ink-jetting a desiccant on a cover plate by an ink-jet printing process for forming a pattern with large surface area and crosslinking the patterned desiccant.

The present invention discloses a package process for organic light-emitting panel. The process comprises ink-jetting a patterned desiccant having large surface area on a cover plate by an ink-jet printing process in inert gas, such as nitrogen; crosslinking the patterned desiccant on the cover plate by a thermal or radiation exposure process in inert gas or under low pressure; compressing the cover plate and the substrate having the organic light-emitting devices; and crosslinking the adhesive frame. In addition, the thickness of the desiccant can be controlled between tens of nano-meters (nm) to hundreds of micrometer (μm) through the selection of the ink-jet printing heads, the concentration of the desiccant and the number of the ink-jet printing process.

In addition, the present invention provides an organic light-emitting panel, which comprises a substrate having organic light-emitting devices; a cover plate over the substrate; a patterned desiccant on the cover plate, facing to the substrate having the organic light-emitting devices; and an adhesive frame between the substrate s and the cover plate. Because the patterned desiccant is formed on the cover plate, the crosslinking time of the patterned desiccant is reduced, the surface area of the desiccant is increased and the moisture absorption of the desiccant is enhanced. Moreover, the pattern of the patterned desiccant has a large surface area, such as continuous, discontinuous, solid or hollow patterns or the combination thereof.

The present invention also provides a coating apparatus, which comprises an ink-jet printing device, a crosslinking device and a buffer chamber. The buffer chamber is connected to the ink-jet printing device and the crosslinking device. The arrangement of the ink-jet printing device, the buffer chamber and the crosslinking device are disposed in consideration of process flow. In addition, the coating apparatus further comprises a loading/unloading unit.

The present invention uses the ink-jet printing process to increase the surface area of the desiccant on the cover plate. Therefore, the solvent within the desiccant can be easily evaporated during crosslinking process. Because of increase of the surface area of the desiccant, the moisture absorption efficiency of the desiccant is also improved.

Additionally, the present invention uses an ink-jet printing heads or devices similar thereto for ink-jetting the desiccant on the cover plate and the desiccant is then crosslinked by a crosslinking process. The process time of the present invention is short and the desiccant is efficiently used. Therefore, the problems of the prior art packaging process are thus resolved, the process time is reduced, the manufacturing costs are also reduced and the organic light-emitting device is being protected.

Moreover, the package process for organic light-emitting panel of the present invention can protect the organic light-emitting devices from erosion due to moisture and oxygen.

In order to make the aforementioned and other objects, features and advantages of the present invention understandable, a preferred embodiment accompanied with figures is described in detail below.

### BRIEF DESCRIPTION OF THE DRAWINGS

FIG. 1 is a schematic process flow showing a first exemplary desiccant ink-jetting process of the present invention.

FIG. 2 is a schematic process flow showing a second exemplary desiccant ink-jetting process of the present invention.

FIG. 3 is a schematic cross-sectional process flow showing the packaging process of organic light-emitting panel.

FIG. 4 is a top and cross-sectional views showing the cover plate and the desiccant of a third embodiment of the present invention.

FIG. 5 is a schematic configuration showing a coating apparatus applied in the fourth embodiment of the present invention.

### DESCRIPTION OF SOME EMBODIMENTS

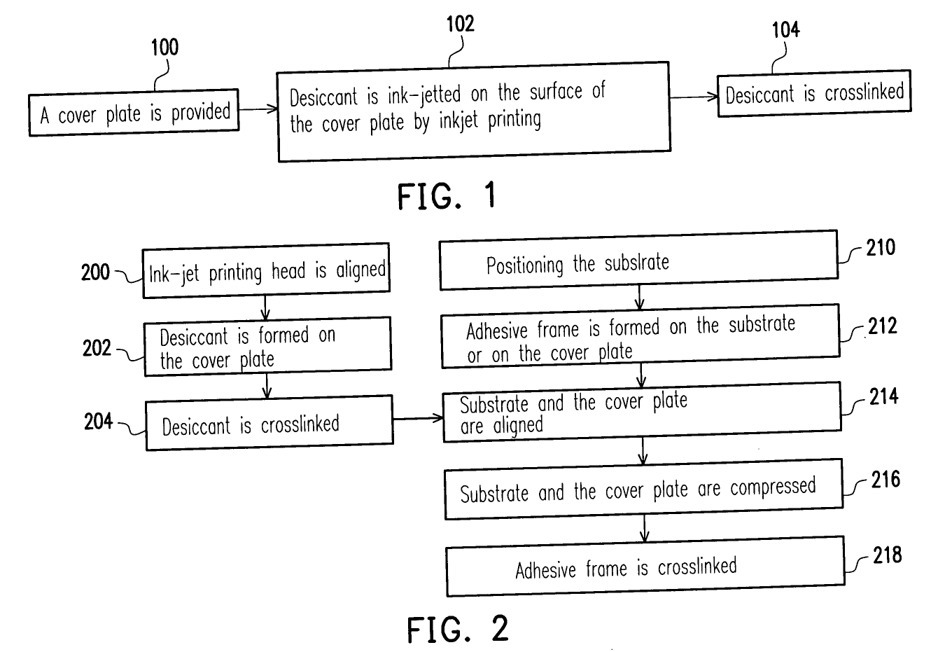

FIG. 1 is a schematic process flow showing a first exemplary desiccant ink-jetting process of the present invention.

Referring to FIG. 1, a cover plate having a plane surface or notches is provided in step 100. Desiccant is ink-jetted on the cover plate by an ink-jet printing process in step 102. In this embodiment of the present invention, an ink-jet printing head or devices similar thereto are used for ink-jetting the desiccant with large surface area on the cover plate. The desiccant can be ink-jetted on either plane or notched cover plate, wherein the desiccant can be crosslinked by performing either a thermal treatment or radiation treatment. The desiccant is then crosslinked in step 104. If the desiccant is thermally crosslinked, the crosslinking of the desiccant is performed by a thermal process; if the desiccant is a radiated crosslinked, the crosslinking of the desiccant is performed by a radiation exposure process having appropriate wavelength and for an appropriate operation time.

The present process has a short process time and efficiently uses the desiccant. In addition, the thickness of the desiccant can be controlled between tens of nm to hundreds of μm through the selection of the ink-jet printing heads, the concentration of the desiccant and the number of the ink-jet printing process.

The second preferred embodiment of the present invention is described below. The present invention can be applied to fabrications of displays or panels similar thereto having organic light-emitting devices. In this embodiment, the present invention is applied to the package process of organic light-emitting panel as shown in FIG. 2. First, the cover plate, and the substrate having organic light-emitting devices are formed, then both of them are assembled during the package process.

FIG. 2 is a schematic process flow showing a second exemplary desiccant ink-jetting process of the present invention.

An ink-jet printing head or devices similar thereto used for performing the ink-jet printing process are aligned to the cover plate in process 200, wherein the cover plate can have a plane surface or notches, and can be made of a glass, a plastic or a flexible substrate. The desiccant can be formed on the cover plate by the ink-jet printing process using an ink-jet printing head or devices similar thereto in inert gas shown in step 202, wherein the desiccant can be thermally crosslinked or radiated crosslinked.

The desiccant is then crosslinked in step 204. If the desiccant is thermally crosslinked, the crosslinking of the desiccant is performed by a thermal process; if the desiccant is a irradiated crosslinked, the crosslinking of the desiccant is performed by a radiation exposure process having appropriate wavelength and for an appropriate operation time.

Providing a substrate having organic light-emitting devices in step 210, wherein the substrate can be a glass, plastic or flexible substrate. An adhesive frame is formed between the substrate having organic light-emitting devices and the cover plate in step 212. The adhesive frame can be thermally crosslinked or irradiated crosslinked. The substrate having organic light-emitting devices and the cover plate are aligned to each other in step 214. A compression step of the substrate and the cover plate is performed in step 216. The adhesive frame is then crosslinked in step 218. If the adhesive frame is thermally crosslinked, the crosslinking of the adhesive frame is performed by a thermal process; if the adhesive frame is a irradiated crosslinked, the crosslinking of the adhesive frame is performed by a radiation exposure process having appropriate wavelength and for an appropriate operation time.

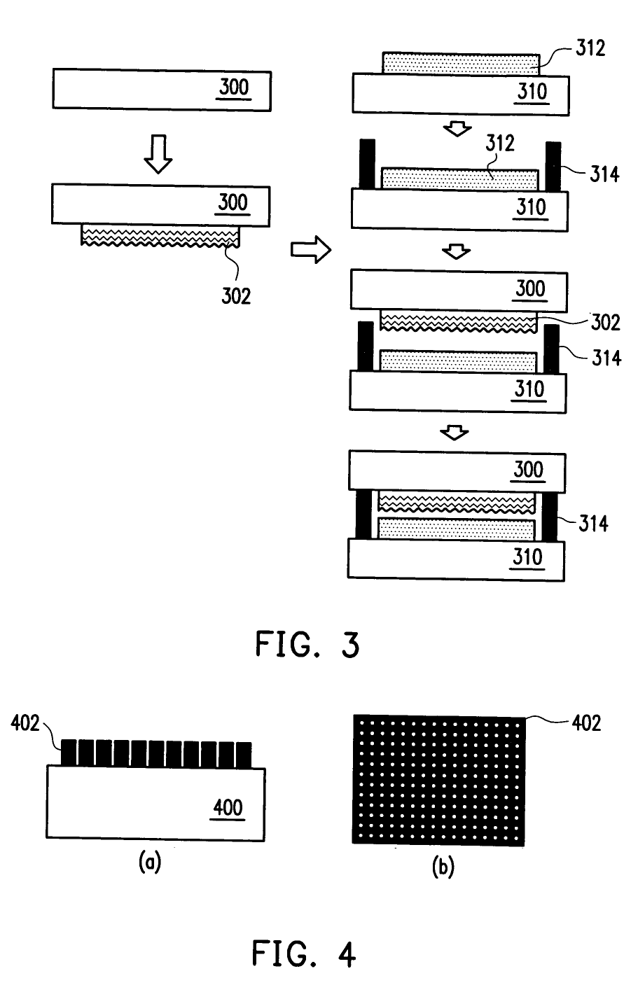

FIG. 3 is a schematic cross-sectional process flow showing the packaging process of organic light-emitting panel and FIG. 3 is used to describe the exemplary process of the present invention in detail.

Referring to FIG. 3, a desiccant 302 is formed on a cover plate 300 by an ink-jet printing process. The desiccant 302 on the cover plate 300 is then crosslinked. An adhesive frame 314 between a substrate 310 having organic light-emitting devices 310 and the cover plate 300 having the desiccant 302 is provided. The substrate 310 having organic light-emitting devices 312 and the cover plate 300 having the desiccant 302 are aligned to each other. The cover plate 300 and the substrate 310 having the organic light-emitting diodes are compressed. Finally, the adhesive frame 314 is crosslinked. The package of the organic light-emitting panel is complete.

The following description is a third preferred embodiment of the present invention. The present invention also provides an organic light-emitting panel which is capable of increasing the surface area of the desiccant, reducing the crosslinking time of the desiccant and enhancing the moisture absorption of the desiccant. For the purpose of simplification, FIG. 4 just illustrates the arrangement of the desiccants 402 on the cover plate 400; the structure of the cover plate 400 and the substrate having the organic light-emitting devices is shown in FIG. 3.

FIG. 4 is a top and cross-sectional views showing the cover plate and the desiccant of a third embodiment of the present invention. Referring to FIG. 4(a), a patterned desiccant 402 is formed on the cover plate 400. The pattern of the desiccant 402 having a large surface area is formed by an ink-jet printing process, wherein the pattern of the desiccant can be a continuous shape as shown in FIG. 3, a discontinuous shape, such as triangle, rectangle, polygon, circle or a random shape in solid or hollow. Therefore, the solvent within the desiccant can be easily evaporated during the crosslinking process and the moisture absorption efficiency of the desiccant is improved.

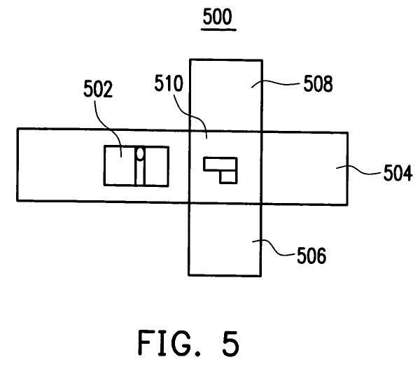

The fourth preferred embodiment of the present invention is described below. The present invention also provides a coating apparatus as shown in FIG. 5. FIG. 5 is a schematic configuration showing a coating apparatus applied in the fourth embodiment of the present invention. Referring to FIG. 5, the coating apparatus 500 comprises an ink-jet printing device 502, a crosslinking device 508 and a buffer chamber 510 for transferring the cover plate, wherein the ink-jet printing device 502 is, for example, at least one ink-jet printing head or devices similar thereto. The buffer chamber 510 is connected to the ink-jet printing device 502 and the crosslinking device 508. The arrangement of the ink-jet printing device 502, the buffer chamber 510 and the crosslinking device 508 are disposed in consideration of process flow. In addition, the coating apparatus further comprises a loading unit 504 and an unloading unit 506 for facilitating transfer of cover plates. The loading unit and unloading unit can be integrated to be a loading/unloading unit (not shown). Moreover, the numbers of the ink-jet printing device 502, the buffer chamber 510 and the crosslinking device 508 are not limited to one; they can be more than one.

Referring to FIG. 5, the cover plate is transferred into the crosslinking device 508 after the ink-jet printing process is complete. The cover plate is then transferred from crosslinking device 508 to the buffer chamber 510 and transferred out of the coating apparatus 500. In addition, the crosslinking device 508 in the coating apparatus 500 applied in the present invention can be replaced depending on the type of the desiccant. For example, the crosslinking device 508 is a crosslinking oven when the desiccant is thermally crosslinked; the crosslinking device 508 is a radiation exposure equipment when the desiccant is crosslinked by radiation.

As described above, the present invention provides an ink-jet printing process to increase the surface area of the desiccant on the cover plate. Therefore, the solvent within the desiccant can be easily evaporated during crosslinking process. Because of increase of the surface area of the desiccant, the moisture absorption efficiency of the desiccant is also improved. In addition, the present invention uses an ink-jet printing head or devices similar thereto for ink-jetting the desiccant on the cover plate and crosslinks the desiccant by a crosslinking process. The process time of the present invention is short and the desiccant is efficiently used. Therefore, the issue of the prior art packaging process is resolved, the process time is reduced, the manufacturing costs are also reduced and the organic light-emitting device is protected. Moreover, the package process for organic light-emitting panel of the present invention can protect the organic light-emitting devices from erosion due to moisture and oxygen. Finally, the present invention can be applied to displays with organic light-emitting panel, inorganic light-emitting panel, field illumination panel, liquid crystal display panel, etc.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A process for packaging an organic light-emitting panel, comprising:
forming a patterned desiccant on a cover plate by ink-jet printing;
crosslinking the patterned desiccant;
providing an adhesive frame between a substrate having organic light-emitting diodes and the cover plate;
compressing the cover plate and the substrate; and
crosslinking the adhesive frame.

2. The process for packaging an organic light-emitting panel of claim 1, wherein the desiccant comprises thermally crosslinked desiccant.

3. The process for packaging an organic light-emitting panel of claim 2, wherein the step of crosslinking the desiccant is performed by a thermal process.

4. The process for packaging an organic light-emitting panel of claim 1, wherein the desiccant comprises a radiated crosslinked desiccant.

5. The process for packaging an organic light-emitting panel of claim 4, wherein the step of crosslinking the desiccant is performed by a radiation exposure process.

6. The process for packaging an organic light-emitting panel of claim 1, wherein the step of crosslinking the desiccant is performed in inert gas and/or under low pressure environment.

7. The process for packaging an organic light-emitting panel of claim 1, wherein the adhesive frame comprises thermally crosslinked frame.

8. The process for packaging an organic light-emitting panel of claim 7, wherein the step of crosslinking the adhesive frame is performed by a thermal process.

9. The process for packaging an organic light-emitting panel of claim 1, wherein the adhesive frame comprises a radiated crosslinked frame.

10. The process for packaging an organic light-emitting panel of claim 9, wherein the step of crosslinking the adhesive frame is performed by a radiation exposure process.

11. The process for packaging an organic light-emitting panel of claim 1, further comprising aligning the substrate having the organic light-emitting diodes to the cover plate with the patterned desiccant thereon prior to the step of compressing the cover plate and the substrate.

12. A method of forming desiccant, comprising:
providing a substrate;
ink-jetting a desiccant on the cover plate by ink-jet printing; and
crosslinking the desiccant.

13. The method of forming desiccant of claim 12, wherein the desiccant comprises thermally crosslinked desiccant.

14. The method of forming desiccant of claim 13, the step of crosslinking the desiccant is performed by a thermal process.

15. The method of forming desiccant of claim 12, wherein the desiccant comprises a radiated crosslinked desiccant.

16. The method of forming desiccant of claim 15, wherein step of crosslinking the desiccant is performed by a radiation exposure process.

17-23. (canceled)
